(19) United States
(12) Patent Application Publication
(10) Pub. No.: US 2013/0168233 A1
(43) Pub. Date: Jul. 4, 2013

(54) APPARATUS AND METHODS FOR HETEROEPITAXIAL GROWTH USING PULSED LASER AND SPUTTERING DEPOSITION WITH REAL-TIME, IN SITU RHEED IMAGING

(71) Applicants: Chang-Beom Eom, Madison, WI (US); Chad M. Folkman, Chicago, IL (US)

(72) Inventors: Chang-Beom Eom, Madison, WI (US); Chad M. Folkman, Chicago, IL (US)

(73) Assignee: Wisconsin Alumni Research Foundation

(21) Appl. No.: 13/342,766

(22) Filed: Jan. 3, 2012

(51) Int. Cl. C23C 14/35; C23C 26/00

(52) U.S. Cl. 204/192.13; 204/298.15

(57) ABSTRACT

Apparatus and methods for the heteroepitaxial growth of multilayered structures using an integrated magnetron sputtering and PLD with continuous, in situ, real-time RHEED imaging are provided. The apparatus for carrying out the methods are equipped with a magnetron sputtering system, a PLD system and a RHEED system associated with a single vacuum chamber.

### REFERENCE TO GOVERNMENT RIGHTS

This invention was made with government support under W911NF-09-1-0368 awarded by the ARMY. The government has certain rights in the invention.

### BACKGROUND

Magnetron sputtering and pulsed laser deposition (PLD) are two physical vapor deposition techniques used to grow thin-films of materials. However, both of these techniques are high vacuum deposition techniques, which limits the available options for the real-time, in situ monitoring of films grown by these techniques.

Reflection high energy electron diffraction (RHEED) is a technique that can be used to monitor film growth on the atomic length scale. Although RHEED has been used to monitor film growth via PLD by employing a differentially-pumped RHEED gun, its use in monitoring film growth via magnetron sputtering in situ and in real time has been hindered by experimental challenges presented by the magnetron sputtering process. For example, the strong magnetic field associated with the permanent magnet in a magnetron sputtering system has the ability to alter the trajectory of the electrons emitted from the RHEED gun and, therefore, tends to distort or bend the path of the electron beam.

In view of the challenges presented by the combination of RHEED and magnetron sputtering, in those relatively rare instances where RHEED is used to study film deposition via magnetron sputtering, it is frequently used to conduct post-deposition surface analysis. In some instances this is conducted in a cluster apparatus, in which different physical vapor deposition processes and material analysis techniques are carried out in separate processing chambers with sample transfer between the chambers. Unfortunately such post-deposition analysis techniques and cluster systems are inefficient because they require multiple sample alignment and re-alignment steps, are mechanically complex and have the potential to introduce impurities into the sample.

While these known methods for using RHEED in combination with magnetron sputtering may be suitable for some applications, they are poorly suited for monitoring the controlled, real-time growth of thin films for devices requiring precise crystal structures at the nanoscale.

### SUMMARY

Apparatus and methods for the heteroepitaxial growth of multilayer structures using a combination of magnetron sputtering and PLD with continuous, in situ, real-time RHEED imaging are provided.

One embodiment of the apparatus comprises a vacuum chamber; a movable substrate holder housed within the vacuum chamber; a PLD system; a magnetron sputtering system; and a RHEED system. The PLD system comprises a pulsed laser deposition target housed within the vacuum chamber and a laser. The pulsed laser deposition target and the laser are configured to deposit material from the pulsed laser deposition target onto a growth substrate held by the substrate holder when the substrate holder is in a first position within the vacuum chamber. The magnetron sputtering system comprises a magnetron sputtering source comprising a sputtering target disposed over a magnet. The sputtering source is configured to deposit material from the sputtering target onto a growth substrate held by the substrate holder when the substrate holder is in a second position within the vacuum chamber. The RHEED system comprises an electron gun, a RHEED screen, and a camera. The electron gun, the RHEED screen and the camera are configured to record RHEED patterns from the growth substrate when the substrate holder is in the first position and when the substrate holder is in the second position.

One embodiment of the methods comprises the steps of depositing a layer of a first material onto a growth substrate via pulsed laser deposition from a pulsed laser deposition target when the growth substrate is in a first deposition position in a vacuum chamber; imaging RHEED patterns of the layer of first material as it is deposited via pulsed laser deposition in situ and in real-time with a RHEED system; moving the growth substrate from the first deposition position to a second deposition position within the vacuum chamber; depositing a layer of a second material onto the layer of first material via magnetron sputtering from a magnetron sputtering target while the growth substrate is in the second deposition position; and imaging RHEED patterns of the layer of second material as it is deposited via magnetron sputtering in situ and in real-time with the same RHEED system. In some embodiments, the growth substrate can be switched between the first and second deposition positions by a simple 180° rotation of the substrate.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

FIG. 1 is a schematic diagram of a top, cross-sectional view of an apparatus for the epitaxial growth of heterostructures using a combination of magnetron sputtering and PLD with in situ, real-time monitoring by RHEED.

FIG. 2 is a schematic diagram showing a more detailed view of some of the magnetron sputtering system and RHEED components of the apparatus of FIG. 1. Two geometries of the magnetron sputtering source are shown: on-axis (FIG. 2a) and off-axis (FIG. 2b). The incident and reflected wave vectors kₒ and k′ are shown, respectively.

FIG. 3 is a schematic diagram showing a more detailed view of some of the PLD system and RHEED components of the apparatus of FIG. 1. The incident and reflected wave vectors kₒ and k′ are shown, respectively.

FIG. 4 is a system level diagram of the apparatus of FIG. 1, showing the gas flow and control systems.

FIG. 5 shows an out-of-plane x-ray diffraction scan of the Re/MgO/Al(poly) tri-layered hetero structure.

FIG. 6(a) shows the possible pressure and growth substrate temperature variations during the heterostructure growth sequence for the Re/MgO/Al heterostructure of FIG. 5. FIG. 6(b) shows RHEED images taken at times I, II, III and IV during the growth sequence shown in FIG. 6(b).

### DETAILED DESCRIPTION

Apparatus and methods for the layer-by-layer deposition of heterostructures with atomically-sharp interfaces are provided. Using the present apparatus and methods, thin layers of single-crystalline materials having nano-scale (i.e., ≦500 nm) dimensions (e.g., thicknesses) can be grown epitaxially using a combination of magnetron sputtering and plasma vapor deposition with real-time, in-situ RHEED analysis of the surface structure and growth dynamics of the growing heterostructure in a single growth chamber. Multilayered heterostructures that can be fabricated using the apparatus and methods include heterostructures comprising alternating layers of dissimilar materials, including layers of metals, semiconductors and electrically insulating materials. Such materials find applications in a variety of devices, including solid state quantum computing devices.

The methods comprise depositing a layer of a first material onto a growth substrate via one of either magnetron sputtering or PLD, while the growth substrate is in a first deposition position in a vacuum chamber, subsequently moving the growth substrate from the first deposition position into a second deposition position within the vacuum chamber, and then depositing a layer of a second material onto the layer of first material via the other of either magnetron sputtering or PLD while the growth substrate is in the second deposition position. During both the magnetron sputtering and PLD processes, a single RHEED system can be used to continuously monitor the layers of the structure as they are deposited.

Apparatus designed to carry out the present methods are able to integrate RHEED, which is a high vacuum technique, with sputtering and PLD, which are carried out at relatively high pressures, in a single vacuum chamber. This design minimizes the need for sample transfer and sample re-alignment between layer depositions and requires only a single RHEED system to monitor the sputtering and PLD growth.

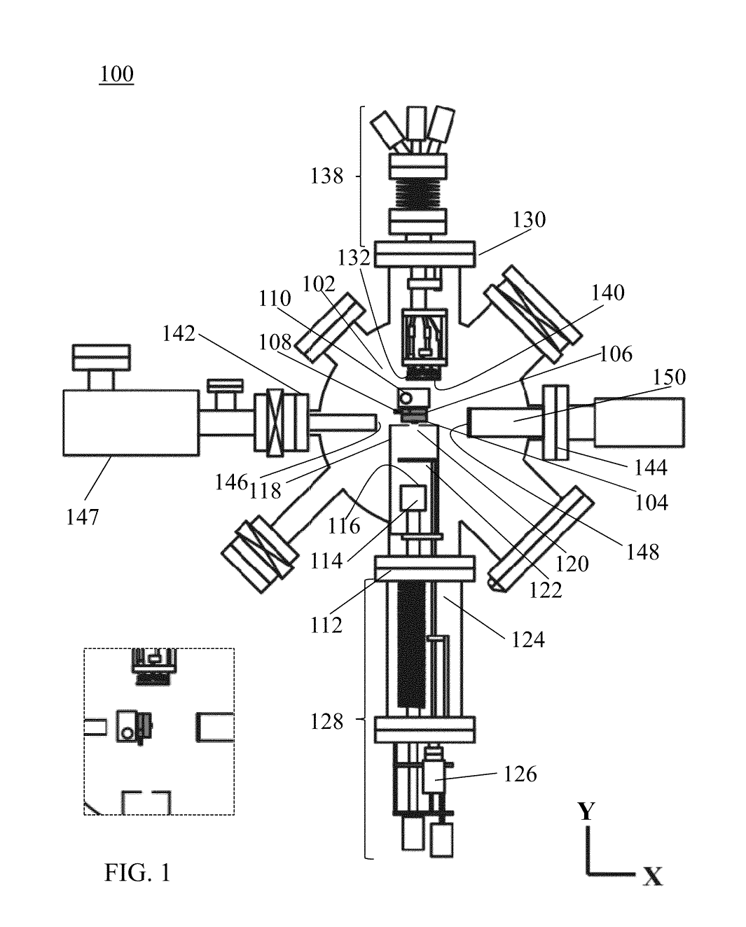

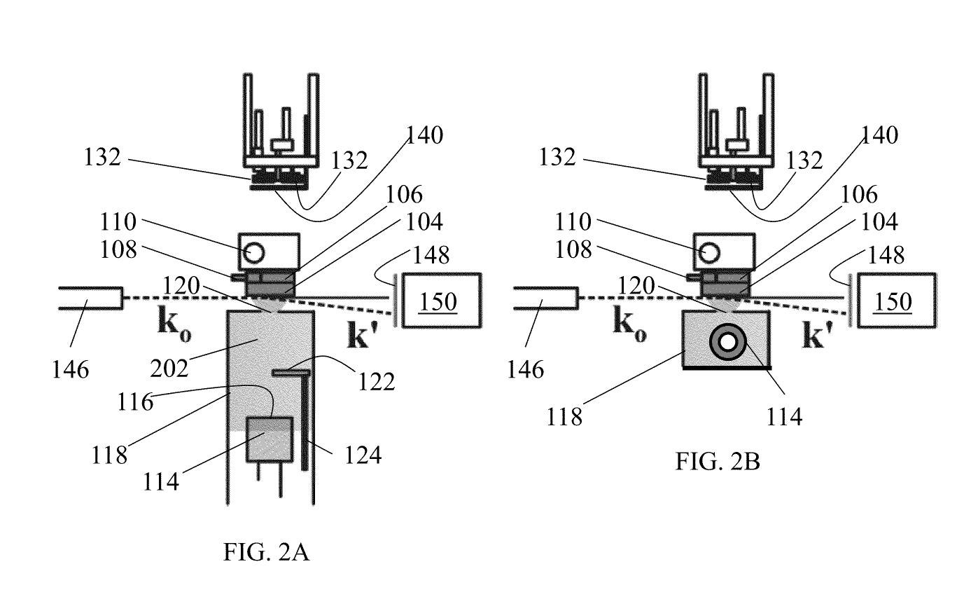

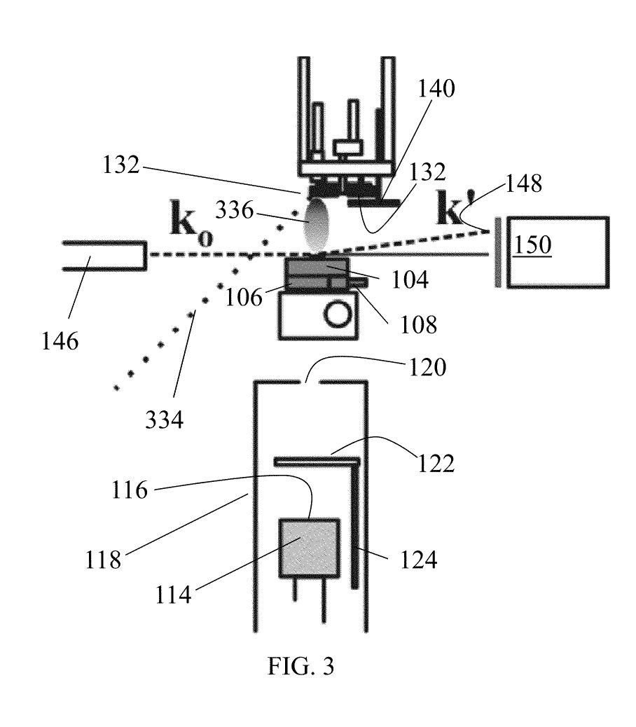

A schematic diagram showing a cross-sectional top view of an apparatus for carrying out the present methods is provided in FIG. 1. The apparatus 100 includes a vacuum chamber 102 housing a growth substrate 104. A magnetron sputtering system, a PLD system and a RHEED system are mounted to and/or within vacuum chamber 102. FIGS. 1, 2 and 3 show the apparatus with the growth substrate in configurations for magnetron sputtering (FIGS. 1 and 2) and for PLD (FIG. 3). However, the growth substrate can easily be moved into a third position when both deposition sources are inactive to allow the growth substrate or substrate holder and the PLD targets (discussed below) to be conveniently accessed for loading or unloading, through use of a load lock and load arm or manual. An example of such a third position is shown in the inset of FIG. 1.

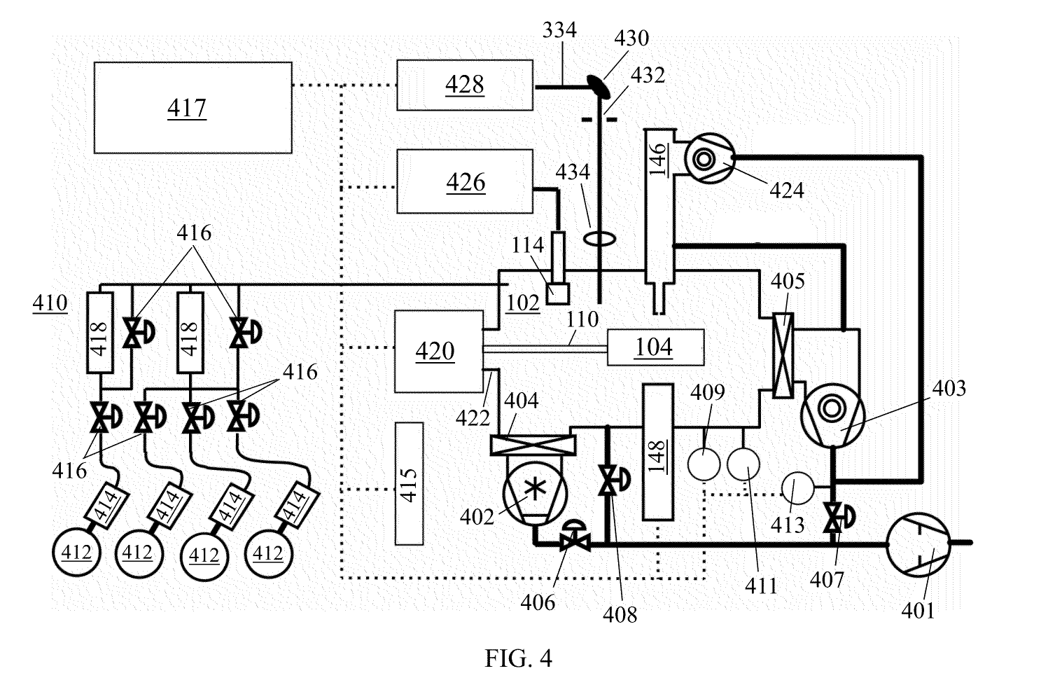

Vacuum chamber 102 is a high vacuum (or, desirably, an ultrahigh vacuum) chamber capable of maintaining a base pressure of 2×10⁻⁸ Torr or lower. The vacuum chamber is connected to one or more pumping stages through one or more pumping ports in the chamber wall. FIG. 4 provides a system level diagram that illustrates a pumping system that can be used to evacuate vacuum chamber 102. (As a system level diagram, FIG. 4 is intended to show the connectivity between the gas flow and control systems external to vacuum chamber 102 and the growth substrate and components of the PLD, sputtering and RHEED systems internal to vacuum chamber 102. It is not intended to provide a representation of the relative positions and geometries of the systems and growth substrates with respect to one another.) This system includes a mechanical pump 401 for roughing out the chamber and a cryo-pump 402 for evacuating the chamber to the desired base pressure. Mechanical pump 401 can also be used to regenerate cryo-pump 402. Air flow from vacuum chamber 102 to cryo-pump 402 can be controlled by gate valve 404. Additional valves 406 and 408 can be used to further regulate air flow. Evacuation of vacuum chamber 102 is further assisted by a turbomolecular pump 403 backed by mechanical pump 401. Air flow is controlled from vacuum chamber 102 to turbomolecular pump 403 by gate valve 405 and air flow from turbomolecular pump 403 to mechanical pump 401 can be controlled by pneumatic valve 407. The vacuum pressure in vacuum chamber 102 can be monitored using a capacitance manometer 409 in combination with a cold cathode gauge 411 and a capacitance gauge 413. Feedback from these pressure gauges can be used to control the pressure in vacuum chamber 102 using a computer 417 interface. On/off pneumatic valve positions are controlled by valve controller manifold 415.

Vacuum chamber 102 is in fluid communication with a gas source manifold via one or more gas inlet ports in the chamber wall. FIG. 4 illustrates a source gas manifold 410 that includes a plurality of gas sources 412 containing sputtering and plasma gases for use during magnetron sputtering and PLD. The flow of gases from gas sources 412 to vacuum chamber 102 can be controlled by a series of regulators 414, pneumatic valves 416 and mass flow controllers 418.

Growth substrate 104 is housed within vacuum chamber 102. Growth substrate 104 comprises a material suitable for use in the growth of the initial layer of a heterostructure. Therefore, the composition of the growth substrate will depend on the composition of the structure to be grown thereon. By way of example only, if the initial layer of the heterostructure is a layer of transition metal oxide, the growth substrate may be a c-plane sapphire substrate. Other examples of suitable growth substrates include materials having a diamond cubic structure (e.g., silicon), a fluorite structure (e.g., HfO₂), a perovskite structure (e.g., SrTiO₃), a rocksalt structure (e.g., MgO), a wurzite structure (e.g., ZnO), a rutile structure (e.g., TiO₂), a corundum structure (e.g., α-Al2O₃) and a spinel structure (e.g., CoFe₂O₄).

Growth substrate 104 is mounted to a substrate holder 106. Substrate holder 106 may be a heater connected to a thermocouple 108 for regulating the temperature of growth substrate 104. In the embodiment depicted in FIG. 1, substrate holder 106 is mounted to shaft 110 which is connected to a rotational stage (φ) configured to move the shaft through an arc in the xy plane (see FIG. 1) around the center of the growth substrate surface. In addition, shaft 110 may be connected to a translational stage, or stages, which allow the growth substrate to be translated in the x, y and z directions and rotated in χ within vacuum chamber 102. As shown in FIG. 4, the heater controller, the rotational stages and the translational stages can be arranged in a substrate control manifold 420 that is connected to the substrate holder through a controller port 422 in the vacuum chamber wall.

Moving the growth substrate from a first position for the deposition of a layer of a first material via a first physical vapor deposition technique to a second position for the deposition of a layer of a second material via a second physical vapor deposition technique can be accomplished using the rotational stages, the translational stages, or both. For example, in some embodiments of the present methods, growth substrate 104 can be moved from the first position to the second position by moving shaft 110 through an arc of 180° in the xy plane, such that the surface of the growth substrate is effectively “reflected” through a plane coincident with its surface. The first and second physical vapor deposition techniques can be magnetron sputtering and PLD, respectively, or vice versa.

In the apparatus shown in FIG. 1, a magnetron sputtering system is mounted to vacuum chamber 102 through a flange 112. A more detailed view of the components of the magnetron sputtering system that reside within vacuum chamber 102 is provided in FIGS. 2(a) and (b). Magnetron sputtering with radio frequency (RF) or direct current (DC) power can be used to deposite a variety of materials in reactive or non-reactive environments. In the present apparatus, the sputtering source can be mounted on-axis (orthogonal to the growth substrate plane) (FIG. 2(a)), off-axis (parallel to the growth substrate plane) (FIG. 2(b)) and at any intermittent angle in between.

The magnetron sputtering system includes at least one sputtering source 114 that includes a sputtering target having a sputtering surface 116 and one or more magnets mounted to the sputtering target, opposite sputtering surface 116. An RF or DC power supply 426 is connected to the magnets and configured to apply a negative voltage to the sputtering target. In addition, the magnetron sputtering system includes a sputtering plasma gas source in fluid communication with the vacuum chamber to provide a gaseous plasma (e.g., argon) during the magnetron sputtering process. In the present apparatus, the sputtering source extends into the vacuum chamber and can be surrounded by a shield 118. Shield 118 is made from a material, such as μ-metal, that shields the electron beam emitted from the RHEED gun from the magnets in the sputtering system and, thereby, prevents or minimizes the deflection of the electron beam by the magnetic and electric fields of the magnetron when the RHEED system and the magnetron sputtering system are operating simultaneously. In addition, shield 118 constrains the plasma 202 generated by the sputtering source within the shield, allowing it to exit only through an aperture 120 at its distal end when the sputtering system is in operation. The sputtering system may further include a shutter 122 configured to be positioned between aperture 120 and sputtering target surface 116 when the magnetron is presputtering or not in operation in order to minimize sputtering target contamination when the PLD system is in operation. Shutter 122 is mounted to a shaft 124 having a handle 126 that allows the shutter to be pivoted in and out of position.

As shown in FIG. 2, when the magnetron sputtering system is in operation, the surface of growth substrate 104 is positioned in front of aperture 120 so that material from the sputtering target is deposited on the growth substrate surface. The sputtering target comprises a material capable of being sputtered onto a substrate surface to provide a layer of the heterostructure. (For the purposes of this disclosure, once a material is deposited onto the growth substrate, that material is itself considered to be part of the growth substrate.) The material can be, for example, a dielectric material, such as an oxide, a semiconducting material, or an electrically conducting or superconducting material. However, magnetron sputtering is particularly well-suited for the deposition of metals. Examples of metals from which the sputtering target (or targets, if multiple targets are used) can be comprised include gold (Au), platinum (Pt), silver (Ag), rhenium (Re), chromium (Cr), titanium (Ti) and combinations thereof.

Sputtering source 114 is mounted to a translational stage 128. Translational stage 128 is configured to translate sputtering source 114 in the y-direction so that the distance between growth substrate 104 and sputtering source 114 can be optimized for deposition. By way of illustration, a typical distance between the sputtering surface of the sputtering target and the surface of the growth substrate is in the range from about 5 to about 20 cm. Translational stage 128 also enables sputtering source 114 to be moved away from growth substrate 104 when it is not in operation, as shown in FIG. 3. This is advantageous because it allows the heater stage to rotate (φ) and minimizes the interaction between the electron beam from the RHEED system and the magnetron sputtering magnets during the PLD deposition process.

Like the magnetron sputtering system, the PLD system of the apparatus can be mounted to vacuum chamber 102 through a flange 130. The PLD system includes one or more PLD targets 132, comprising a material to be deposited on the growth substrate, and a laser 428 configured to focus a laser beam at the surface of the PLD target. As shown in FIG. 4, the laser beam may be directed and focused using a series of mirrors 430, apertures 432 and lenses 434. The PLD system may further include a shutter 140 configured to be positioned between PLD target 132 and growth substrate 104 when the PLD system is not in operation in order to protect the PLD target from contamination when the magnetron sputtering system is in operation.

Like the sputtering target, the PLD target may comprise an electrically insulating material or an electrically conducting material. However, target materials having low thermal conductivities, low optical reflectance and high absorption are favored. Such materials include transition metal oxides, such as TiO₂, ZnO₂, CeO₃, SrTiO₃, BaTiO₃, PZT and LaFeO₃.

As shown in FIG. 3, when the PLD system is in operation, the surface of growth substrate 104 is disposed opposite and facing the PLD target surface. During the deposition process, the laser emits a laser beam 334 having an energy density and pulse repetition rate sufficient to eject material from the PLD target in a plasma plume 336 which deposits a film of the material on the growing heterostructure. The PLD target may be mounted to a rotating target holder which allows for more uniform ablation of the target material. In the embodiment of the apparatus depicted in FIGS. 1-3, the deposition surface (i.e., the surface of the target from which the material to be deposited is removed) of PLD target 132 is disposed directly opposite and facing the sputtering surface (i.e., the surface of the target from which the material to be deposited is removed) of sputtering target 116 such that the magnetron sputtering system and the PLD system provide can provide on-axis sputtering from opposite (e.g., separated by 180°) directions.

PLD target 132 is mounted to a translational stage 138. Translational stage 138 is configured to translate PLD target 132 in the z-direction so that the distance between growth substrate 104 and PLD target 132 can be optimized for deposition. By way of illustration, a typical distance between the PLD target surface and the surface of the growth substrate is in the range from about 3 to about 7 cm. Translational stage 138 also enables PLD target 132 to be moved away from growth substrate 104 when the PLD system is not in operation, as shown in FIG. 2.

The components of the RHEED system of the apparatus shown in FIG. 1 are mounted to vacuum chamber 102 through two oppositely disposed flanges 142, 144 in the chamber wall. The components include an electron gun 146 disposed opposite a RHEED screen 148 positioned in front of a RHEED camera 150. The components are positioned such that RHEED images of the growing heterostructure can be obtained, in situ and in real-time during both magnetron sputtering deposition and PLD without changing the position of electron gun 146 or RHEED screen 148.

Electron gun 146 resides in a housing 147 which is differentially pumped with one or more pumping stages. These pumping stages are desirably capable of reduce the local pressure to about 10⁻⁵ Torr or less during operation in order to maintain the brightness at the RHEED screen and to increase the lifetime of the electron gun filament through reduced oxidation. The embodiment shown in FIGS. 1 and 4 has two pumping stages, each of which includes a turbomolecular pump 403, 424 backed by mechanical pump 401. The distal end 152 of the housing extends into vacuum chamber 102 and includes a pinhole aperture 154 through which an electron beam is directed toward the surface of the growth substrate at a grazing angle, as indicated by the incident wave vectors (kₒ) shown in FIGS. 2 and 3.

RHEED screen 148 is positioned such that electrons scattered from the heterostructure surface strike the screen at a grazing angle, as indicated by the reflected wave vectors (k′) shown in FIGS. 2 and 3. Camera 150 images the spots and streaks caused by scattered electrons striking RHEED screen 148.

In one embodiment of a method for growing a heterostructure using the present apparatus an epitaxial single-crystalline dielectric/single-crystalline superconducting thin film heterostructure is grown in a single vacuum chamber. In this method a high quality epitaxial layer of a superconducting material, such as rhenium (Re), is grown via magnetron sputtering on a suitable growth substrate (e.g., c-plane sapphire) with in situ, real-time imaging by high pressure RHEED while the growth substrate is in a first deposition position. The growth substrate is then moved into a second deposition position and a high quality epitaxial layer of a dielectric material is grown via PLD on the layer of superconducting material with in situ, real-time imaging using the same RHEED system. By alternating the position of the growing heterostructure between the magnetron sputtering deposition position and the PLD position, a heterostructure with the desired number of layers can be grown.

Prior to carrying out the present methods for heteroepitaxial growth, it is advantageous to establish the positions for the growth substrate during magnetron sputtering and during PLD so that the growth substrate can be rapidly and accurately transferred between the two positions. This can be accomplished by determining the optimal position for the growth substrate surface during the first of the two physical vapor deposition processes—in terms of the x, y, and z Cartesian coordinates and angles φ and χ—and saving these coordinates, then repeating the process for the second of the two physical vapor deposition processes. The coordinates should be determined while the PLD and magnetron sputtering systems are in their operative positions, since the trajectory of the electron beam from the RHEED gun may be altered somewhat by the magnets in the magnetron sputtering source.

### Example

This example illustrates the use of the present apparatus and methods for the fabrication of a Re/MgO/Al heterostructure.

PLD was used to fabricate high quality insulating oxide thin film layers. Such layers, which are useful for qubit circuits, provide low loss (tan δ) dielectrics and good lattice matching to the c-sapphire growth substrate (a=4.76 Å) used in this example. MgO (a=4.21 Å) and α-Al₂O₃ were selected as PLD target materials to meet these requirements. Magnetron sputtering was used to deposit a bottom electrode of (0001) rhenium (a=2.60 Å) and a polycrystalline Al top film.

The apparatus of FIG. 1 was used to fabricate the heterostructure. A 4-target carousel (TSST B.V. Eslde, Holland) mounted on one flange of the vacuum chamber was used to hold the PLD targets. On the opposing side of the chamber two 1.33″ magnetron sputtering targets (MeiVac Inc., San Jose, Calif.) were mounted and powered with a DC power supply (Advanced Energy Inc. Fort Collins, Colo.). Between the sputtering and PLD targets, a resistive heater capable reaching 950° C. in air was inserted (TSST B.V. Eslde, Holland). This resistive heater served as the substrate holder for the c-sapphire growth substrate. The resistive heater was mounted on a 5-axis stepper motor controlled manipulator (X, Y, Z, φ and χ). The tilt-φ rotateed (±360° max.) the heater between PLD and sputtering positions and was also the fine-adjust for fixing the incident angle between the incident wave vector kₒ and the growth substrate plane, ˜2°. The azimuthal-χ angle rotateed (±50° max.) the growth substrate about the surface normal and corrected for misalignments of kₒ with the desired in-plane crystallographic direction of the substrate and deposited films. All five degrees of freedom of the heater mount (X, Y, Z, φ and χ) were controlled through a custom LabView program (Austin, Tex.) making it possible to fully align and index the growth substrate in the PLD and sputtering positions then quickly switch between the stored position coordinates. Small adjusts were used to account for stepper motor backlash.

To maintain optimum working distances between the growth substrate and PLD targets of ˜5 cm, the target stage was mounted on a linear bellows. When the heater mount rotated approximately 180° to switch between the PLD and magnetron sputtering positions, the footprint of the heater and mount in the xy-plane avoided a collision by retracting the carousel away towards the chamber wall ˜3 cm. Similarly, the sputtering gun was mounted on a linear bellows to allow clearance between the μ-metal shield and the rotating heater and heater mount.

The pressure of the system was controlled with a throttle valve between the chamber and a 520 l/s turbo molecular pump (Pfieffer Vacuum GmbH Assiar Germany) Gas was inlet through mass flow controllers or vented through on/off valves. In addition, a cryo-pump was present to facilitate the fast removal of water during pumpdown and quick environmental changes as needed between epi-layers (Brooks Automation, Inc. Chelmsford, Mass.). The base pressure of the system without backout was 2×10⁻⁸ Torr.

The sapphire substrates (Crystec GmbH Berlin, Germany) were annealed in flowing O₂ at 1100° C. for 3 hrs. The 1.33″ diameter, ¼″ thick rhenium and aluminum sputtering targets (>99.99% pure) were used in dual on-axis sputtering sources (Praxair Inc. Danbury, Conn.). The MgO target was fabricated from pure (MgO>99.99%) powder (Alfa Aesar® Ward Hill, Mass.), pressed into a 1″ diameter, ¼″ thick pellet and sintered at 1400° C. for 6 hrs in air to achieve >85% of bulk density. The α-Al₂O₃ PLD target used was a 1″ diameter ⅛″ thick single crystal (Crystec GmbH Berlin, Germany).

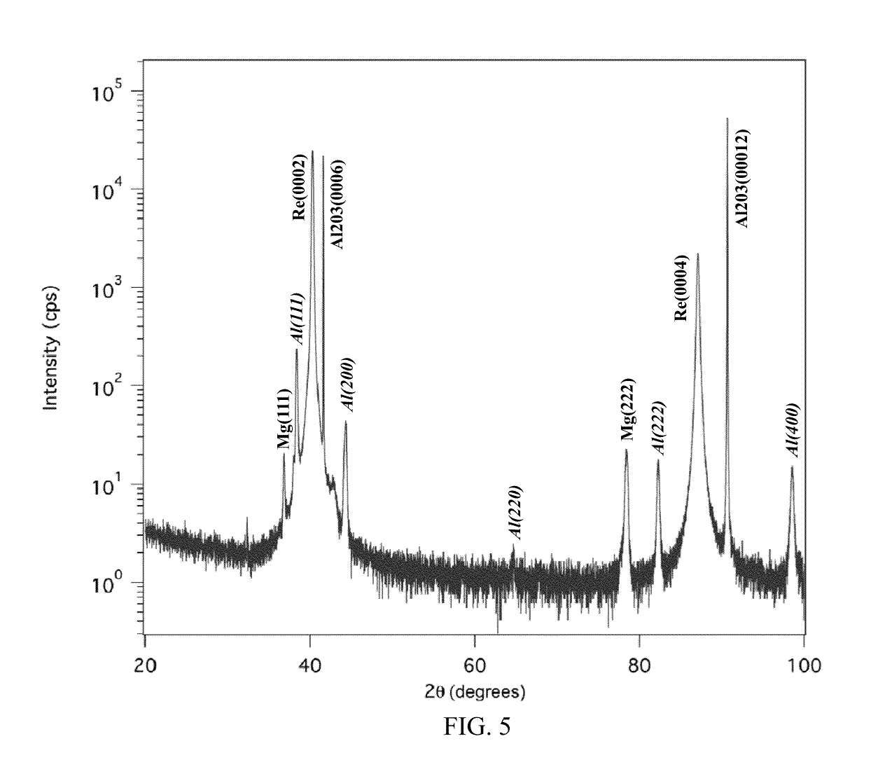

The RHEED intensity from the differentially pumped electron source (STAIB, Inc.) was performed with a CCD camera focused on a phosphorus screen inside the chamber. The in situ analysis was performed with the custom program that was capable of capturing images and scalar intensity values for user selected areas. To confirm epitaxial relationships, high resolution x-ray diffraction (HRXRD) scans were measured ex situ with a four-bounce four circle diffractometer with Cuk_{α1} radiation (D8 Discover, Bruker, Inc. Madison, Wis.). FIG. 5 shows an out-of-plane x-ray diffraction scan of the Re/MgO/Al(poly) tri-layered structure confirming high quality epitaxial growth of the Re and MgO films, consistent with in situ RHEED. Diffraction peaks from the polycrystalline Al top film are also present.

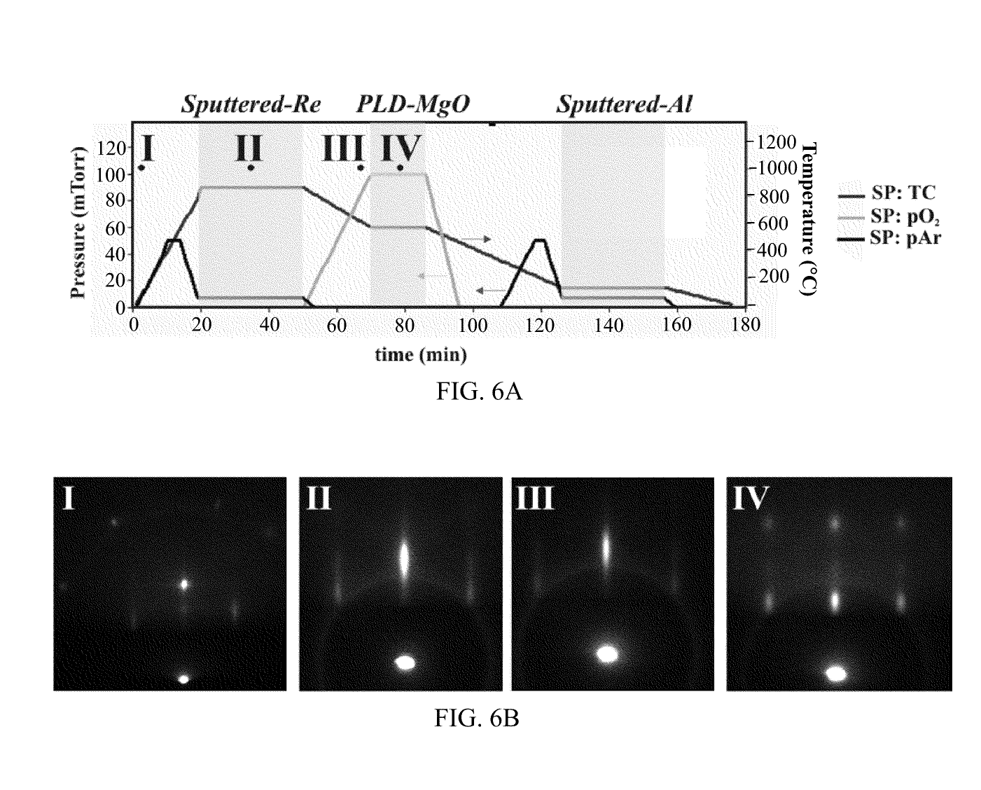

FIG. 6(a) shows the possible pressure and growth substrate temperature variations during the heterostructure growth sequence. The setpoint pressure for pO₂ and pAr and the heater temperature (measured with thermocouple TC) are shown in the graph of FIG. 6(a). RHEED images taken at times I, II, III and IV during the growth sequence are shown in FIG. 6(b). The c-sapphire growth substrate (I) and the Re layer (II and III) exhibited a smooth surface, while the MgO layer (IV) exhibited a three-dimensional (i.e., rougher) surface structure.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure, the use of “and” or “or” is intended to include “and/or” unless specifically indicated otherwise.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described in order to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

What is claimed is:

1. An apparatus for the fabrication of heterostructures comprising:
(a) a vacuum chamber;
(b) a movable substrate holder housed within the vacuum chamber;
(c) a pulsed laser deposition system comprising a pulsed laser deposition target housed within the vacuum chamber; and a laser; wherein the pulsed laser deposition target and the laser are configured to deposit material from the pulsed laser deposition target onto a growth substrate held by the substrate holder when the substrate holder is in a first position within the vacuum chamber;
(e) a magnetron sputtering system comprising a magnetron sputtering source comprising a sputtering target disposed over a magnet; wherein the sputtering source is configured to deposit material from the sputtering target onto a growth substrate held by the substrate holder when the substrate holder is in a second position within the vacuum chamber; and
(f) a RHEED system comprising: an electron gun; a RHEED screen; and a camera; wherein the electron gun, the RHEED screen and the camera are configured to record RHEED patterns from the growth substrate when the substrate holder is in the first position and when the substrate holder is in the second position.

2. The apparatus of claim 1, wherein the substrate holder is configured to move from the first position to the second position by rotating a growth substrate held therein through an in-plane angle of about 180°.

3. The apparatus of claim 1, wherein the pulsed laser deposition target comprises an electrically insulating or semiconducting material and the magnetron sputtering target comprises an electrically conductive material.

4. The apparatus of claim 1, wherein the magnetron sputtering system further comprises a shield disposed around the magnetron sputtering source, the shield defining an aperture configured to be positioned between a growth substrate held in the substrate holder and the sputtering target when the magnetron sputtering system is in operation, wherein the shield comprises a material that shields the electron beam from the electron gun from the magnetic field generated by the magnet when the RHEED system is in operation.

5. The apparatus of claim 1, wherein the sputtering target is configured for on-axis sputtering and further wherein the deposition surface of the pulsed laser deposition target is disposed opposite and facing the sputtering surface of the sputtering target.

6. The apparatus of claim 1, wherein the sputtering target is configured for off-axis sputtering.

7. A method of growing a heterostructure, the method comprising:
(a) depositing a layer of a first material onto a growth substrate via pulsed laser deposition from a pulsed laser deposition target, wherein the growth substrate is in a first deposition position in a vacuum chamber during the pulsed laser deposition;
(b) imaging RHEED patterns of the layer of first material as it is deposited via pulsed laser deposition in situ and in real-time with a RHEED system;
(c) moving the growth substrate from the first deposition position into a second deposition position within the vacuum chamber;
(d) depositing a layer of a second material onto the layer of first material via magnetron sputtering from a magnetron sputtering target while the growth substrate is in the second deposition position; and
(e) imaging RHEED patterns of the layer of second material as it is deposited via magnetron sputtering in situ and in real-time with the RHEED system.

8. The method of claim 7, wherein moving the growth substrate from the first deposition position to the second deposition position comprises, or is equivalent to, rotating a growth substrate held therein through an in-plane angle of about 180°.

9. The method of claim 7, wherein the pulsed laser deposition target comprising an electrically insulating or semiconducting material and the magnetron sputtering target comprises an electrically conductive material.

10. The method of claim 7, wherein the magnetron sputtering target is configured for on-axis sputtering and further wherein the deposition surface of the pulsed laser deposition target is disposed opposite and facing the sputtering surface of the magnetron sputtering target.

11. The method of claim 7, wherein the magnetron sputtering target is configured for off-axis sputtering.

12. The method of claim 1, wherein the RHEED patterns are imaged continuously during the growth of the hetero structure.

13. The method of claim 1, wherein the RHEED system comprises an electron gun and a RHEED screen disposed opposite the electron gun and further wherein the positions of the electron gun and the RHEED screen are the same during the deposition of the layer of a first material onto the growth substrate via pulsed laser deposition and the deposition of the layer of the second material onto the growth substrate via magnetron sputtering.
